(19) United States
(12) Patent Application Publication
(10) Pub. No.: US 2011/0177680 A1
(43) Pub. Date: Jul. 21, 2011

(54) ETCHANT COMPOSITION FOR METAL WIRING AND METHOD OF MANUFACTURING THIN FILM TRANSISTOR ARRAY PANEL USING THE SAME

(75) Inventors: Byeong-Jin LEE, Yongin-si (KR); Hong Sik PARK, Suwon-si (KR); Tai-Hyung RHEE, Daejeon Metropolitan City (KR); Yong-Sung SONG, Daejeon Metropolitan City (KR); Choung-Woo PARK, Daejeon Metropolitan City (KR); Chang-Ho LEE, Daejeon Metropolitan City (KR)

(73) Assignee: Samsung Electronics Co. Ltd.

(21) Appl. No.: 12/902,018

(22) Filed: Oct. 11, 2010

(30) Foreign Application Priority Data
Jan. 19, 2010 (KR) 10-2010-0004930

(51) Int. Cl. H01L 21/20; C09K 13/00; C09K 13/08

(52) U.S. Cl. 438/478; 252/79.1; 252/79.3; 257/E21.09

(57) ABSTRACT

The present invention relates to an etchant for wet etching a wiring that includes copper, where the etchant includes approximately 5 to approximately 25 wt % of a peroxide, approximately 0.5 to approximately 5 wt % of an oxidant, approximately 0.1 to approximately 1 wt % of a fluoride-based compound and approximately 1 to approximately 10 wt % of a glycol. The etchant can provide an etching rate that is suitable to many processes, and produces an appropriate etching amount as well as an appropriate taper angle.

In addition, the etchant exhibits advantages including relatively low viscosity as compared to phosphoric acid-based etchants, relatively uniform etching characteristics, and relative stability as compared to peroxide-based etchants.

### CROSS-REFERENCE TO RELATED APPLICATION

This application claims priority to, and the benefit of, Korean Patent Application No. 10-2010-0004930 filed in the Korean Intellectual Property Office on Jan. 19, 2010, the entire contents of which are incorporated herein by reference.

### BACKGROUND OF THE INVENTION

(a) Field of the Invention

The present invention relates to an etchant for metal wiring, and a manufacturing method for a thin film transistor array panel using the etchant.

(b) Description of the Related Art

Liquid crystal displays commonly display images by operating an array of thin film transistors (TFTs). The gate and drain electrodes of this array of transistors is often fabricated on a substrate by sputtering a metal film onto the substrate, coating a photoresist (PR), selectively exposing and developing the photoresist using the mask, and using the PR to pattern the metal film. This patterning is often accomplished through either dry etching using plasma that is capable of etching only the metal film without damage to the photoresist, or wet etching using an etchant.

The resistance of the wiring that is formed by the above processes is a factor in causing electric signal delay in the thin film transistor liquid crystal display, which in turn hampers implementation of high resolution and improvement in panel size.

Accordingly, in order to lower the electric signal delay of the thin film transistor liquid crystal display, it is desirable to select a metal that has low resistance.

As compared to iron (Fe, specific resistance: 9.68×10-8 Ωm), molybdenum (Mo, specific resistance 5.05×10-8 Ωm), aluminum (Al, specific resistance 2.75×10-8 Ωm), and gold (Au, specific resistance 2.44×10-8 Ωm), copper (Cu, specific resistance 1.69×10-8 Ωm) is advantageous in terms of both cost and resistance. However, since copper is known to adhere poorly to glass and silicon films, its use in liquid crystal display TFTs has often been problematic. Previous efforts have thus focused on compensating for the poor adhesion of copper films by using multilayer films that use copper as a main wiring metal film, and include another metal film having excellent adhesion with glass and or silicon films.

The above information disclosed in this Background section is only for enhancement of understanding of the background of the invention. It therefore may contain information not in the prior art.

### SUMMARY OF THE INVENTION

However, since the multilayer includes a plurality of metal layers having different characteristics, simultaneous etching of multiple layers is challenging.

An exemplary embodiment of the present invention provides an etchant for metal wiring that is capable of etching each layer of a multilayer all together, in a single etching step.

Another exemplary embodiment of the present invention provides a method for manufacturing a thin film transistor array panel using this etchant.

In order to solve the above problem, an etchant for metal wiring according to an exemplary embodiment of the present invention includes approximately 5 to approximately 25 wt % of a peroxide, approximately 0.5 to approximately 5 wt % of an oxidant, approximately 0.1 to approximately 1 wt % of a fluoride-based compound and approximately 1 to approximately 10 wt % of a glycol.

The peroxide may include ammonium persulfate, sodium persulfate, potassium persulfate or a mixture thereof.

The oxidant may include potassium hydrogen sulfate, sodium nitrate, ammonium sulfate, sodium sulfate, sodium hydrogen sulfate or a mixture thereof.

The fluoride-based compound may include acidic ammonium fluoride, fluorosilicic acid, potassium hydrogen fluoride or a mixture thereof.

It may further include a chelating agent.

The chelating agent may include an organic chelating agent that includes an amino group and a carboxyl group.

The chelating agent may include EDTA, iminodiacetic acid, nitrilotriacetic acid, diethylene trinitrilo pentaacetic acid (DTPA) or a mixture thereof.

The glycols may include ethyleneglycol, polyethyleneglycol, glycolic acid or a mixture thereof.

The chelating agent may comprise approximately 0.1 to approximately 5 wt % of the etchant.

It may further include an additive in an amount of approximately 0.1 to approximately 5 wt %.

The additive may further include an azole-based compound.

The etchant may be used to etch a multilayer wiring that includes copper.

The multilayer wiring may include a first layer that includes copper and a second layer that includes titanium or molybdenum.

A method for manufacturing a thin film transistor array panel according to an exemplary embodiment of the present invention includes forming a gate line that includes a gate electrode, forming a data line that crosses the gate line, and forming a semiconductor that overlaps the gate electrode, wherein at least one of the forming a gate line and forming a data line includes layering a multilayer wiring that includes copper, and etching the multilayer wiring with an etchant that includes approximately 5 to approximately 25 wt % of a peroxide, approximately 0.5 to approximately 5 wt % of an oxidant, approximately 0.1 to approximately 1 wt % of a fluoride-based compound, and approximately 1 to approximately 10 wt % of a glycol.

The peroxide may include ammonium persulfate, sodium persulfate, potassium persulfate or a mixture thereof.

The oxidant may include potassium hydrogen sulfate, sodium nitrate, ammonium sulfate, sodium sulfate, sodium hydrogen sulfate or a mixture thereof.

The fluoride-based compound may include acidic ammonium fluoride, fluorosilicic acid, potassium hydrogen fluoride or a mixture thereof.

The etchant may further include a chelating agent.

The etchant may further include an azole-based compound as the additive.

The etchant according to the present invention has the advantage of allowing for etching of a copper film, a copper alloy film, titanium film, titanium alloy film, molybdenum film, molybdenum alloy film or any of these films in a multilayer, where each of the films in the multilayer can be etched together, at the same time. Furthermore, the process can be performed at a lower temperature as compared to other etching compositions.

In addition, when the etching process is performed by an etchant according to the present invention, the etching may be more efficiently performed, so that a loss by the etching is generally 1.0 μm or less and a taper angle is about 20° or more.

In addition, etchants of the present invention have the advantage of avoiding problems related to the high viscosity of traditional phosphoric acid-based etchants, and the stability problems of traditional peroxide-based etchants.

### BRIEF DESCRIPTION OF THE DRAWINGS

FIG. 1 is an electron microscope picture obtained by observing the profile of a titanium film/copper film after etching is performed by using an etching composition according to Example 1 of the present invention;

FIG. 2 is an electron microscope picture obtained by observing a glass film that is subjected to photoresist (PR) stripping of a titanium film/copper film after etching is performed by using an etching composition according to Example 1;

FIG. 3 and FIG. 4 are electron microscope pictures obtained by observing a glass film that is subjected to photoresist stripping of a titanium film/copper film after etching is performed by using an etching composition according to Example 5; and

FIG. 5 is an electron microscope picture obtained by observing a glass film that is subjected to photoresist (PR) stripping of a titanium film/copper film after etching is performed by using an etching composition according to Example 5.

### DETAILED DESCRIPTION OF THE EMBODIMENTS

The present invention will be described more fully hereinafter with reference to the accompanying drawings, in which exemplary embodiments of the invention are shown.

As those skilled in the art would realize, the described embodiments may be modified in various different ways, all without departing from the spirit or scope of the present invention.

What follows are eight examples of etchant mixtures that can be used to etch structures such as multilayer films, according to embodiments of the invention. One of ordinary skill in the art will realize that the mixture components and amounts shown in each example are approximate, and can vary. Additionally, the etching characteristics of each of the etchant mixtures varies by application.

First, the compositional ratio of each exemplary embodiment will be described below.

### Example 1

The etchant was manufactured by mixing 5 wt % of ammonium persulfate, 3 wt % of oxidant, 0.5 wt % of fluoride-based compound, 0.5 wt % of chelating agent, 5 wt % of glycols, and 0.5 wt % of additive, with the remainder of the mixture being deionized water.

The constitutional components and contents of the etchant are described in the following Table 1.

### Examples 2 to 4

The etchants of these examples comprise the same materials as that of Example 1 but, as described in the following Table 1, in different relative amounts. In particular, the etchant of Example 2 was manufactured by mixing 7.5 wt % of ammonium persulfate, 2 wt % of oxidant, 0.5 wt % of fluoride-based compound, 0.5 wt % of chelating agent, 5 wt % of glycols, and 0.45 wt % of additive, with the remainder of the mixture being deionized water.

The etchant of Example 3 was manufactured by mixing 5 wt % of ammonium persulfate, 3 wt % of oxidant, 0.5 wt % of fluoride-based compound, 1.0 wt % of chelating agent, 5 wt % of glycols, and 0.52 wt % of additive, with the remainder of the mixture being deionized water.

The etchant of Example 4 was manufactured by mixing 4 wt % of ammonium persulfate, 2.5 wt % of oxidant, 0.5 wt % of fluoride-based compound, 0.5 wt % of chelating agent, 5 wt % of glycols, and 0.5 wt % of additive, a with the remainder of the mixture being deionized water.

### Examples 5 to 8

The etchants of examples 5 to 8 comprise the same materials as that of Example 1 but, as described in the following Table 2, in different relative amounts.

The etchant of Example 5 was manufactured by mixing 5 wt % of ammonium persulfate, 2 wt % of oxidant, 0.05 wt % of fluoride-based compound, 0.5 wt % of chelating agent, 5 wt % of glycols, and 0.5 wt % of additive, with the remainder of the mixture being deionized water.

The etchant of Example 6 was manufactured by mixing 5 wt % of ammonium persulfate, 2 wt % of oxidant, 1.2 wt % of fluoride-based compound, 0.5 wt % of chelating agent, 5 wt % of glycols, and 0.5 wt % of additive, with the remainder of the mixture being deionized water.

The etchant of Example 7 was manufactured by mixing 30 wt % of ammonium persulfate, 2 wt % of oxidant, 0.5 wt % of fluoride-based compound, 0.5 wt % of chelating agent, 5 wt % of glycols, and 0.5 wt % of additive, with the remainder of the mixture being deionized water.

The etchant of Example 8 was manufactured by mixing 5 wt % of ammonium persulfate, 10 wt % of oxidant, 0.5 wt % of fluoride-based compound, 0.5 wt % of chelating agent, 5 wt % of glycols, and 0.5 wt % of additive, with the remainder of the mixture being deionized water.

TABLE 1

| Etchant composition | Example 1 | Example 2 | Example 3 | Example 4 |
|---|---|---|---|---|
| Ammonium persulfate | 5% | 7.5% | 5% | 4% |
| Oxidant | 3% | 2% | 3% | 2.5% |
| Fluoride-based | 0.5% | 0.5% | 0.5% | 0.5% |
| compound | | | | |
| Chelating agent | 0.5% | 0.5% | 1.0% | 0.5% |
| Glycols | 5% | 5% | 5% | 5% |
| Additive | 0.5% | 0.45% | 0.52% | 0.5% |
| Deionized water | Remainder | Remainder | Remainder | Remainder |

TABLE 2

| Etchant composition | Example 5 | Example 6 | Example 7 | Example 8 |
|---|---|---|---|---|
| Ammonium persulfate | 5% | 5% | 30% | 5% |
| Oxidant | 2% | 2% | 2% | 10% |
| Fluoride-based | 0.05% | 1.2% | 0.5% | 0.5% |
| compound | | | | |
| Chelating agent | 0.5% | 0.3% | 0.5% | 0.5% |
| Glycols | 5% | 5% | 5% | 5% |
| Additive | 0.5% | 0.5% | 0.5% | 0.5% |
| Deionized water | Remainder | Remainder | Remainder | Remainder |

Multilayered metal wirings were etched with each of the above eight etchants. The results are described below.

The multilayer metal wiring that is used in the present experiment has a dual-layer structure with an upper layer that is made of a copper film, and a lower layer that is made of a titanium film.

The test results may be applied in cases that employ multilayer metal wirings that utilize copper alloy film and titanium alloy film.

First, a multilayer wiring was fabricated from a titanium film (lower layer) and a copper film (upper layer) that were layered at the temperature of 28° C. In this experiment, the titanium film had a thickness of approximately 100 Å and the copper film had a thickness of approximately 1200 Å. This wiring was then etched by using the etchants that were manufactured in Examples 1 to 8. More specifically, a photoresist film was formed on the multilayer, patterned, then subjected to an etching process that was performed by spraying etchant onto the multilayer in a uniform spraying manner. Etching was stopped once it exceeded 100% of end point detection. This 100% exceeding etching was performed because the etch rate of the other metal film is relatively slow as compared to the copper film, necessitating extra etching time to ensure that the tail and residual sand from the titanium metal film are sufficiently removed.

Hereinafter, the evaluation of physical properties will be described.

In the present experiment, the etching loss (CD skew) and taper angle were measured. First, the etching loss was obtained by observing the profile of the multilayer (titanium film/copper film) using a scanning electron microscope and measuring the distance between an end of the photoresist and an end of the copper film.

Next, the taper angle was measured by observing the profile of the multilayer (titanium film/copper film) using a scanning electron microscope and visually measuring the taper angle of the etched side.

The results that were obtained by measuring the etching loss and the taper angle using the above method in respects to Examples 1 to 8 are described in Table 3 and Table 4.

TABLE 3

| | Etching loss | Taper | |
|---|---|---|---|
| Evaluation | (CD skew, μm) | angle (°) | Evaluation |
| Example 1 | Excellent | Excellent | Excellent |
| Example 2 | Excellent | Excellent | Excellent |
| Example 3 | Excellent | Excellent | Excellent |
| Example 4 | Excellent | Excellent | Excellent |

TABLE 4

| | Etching loss | Taper | |
|---|---|---|---|
| Evaluation | (CD skew, μm) | angle (°) | Evaluation |
| Example 5 | Excellent | Excellent | Titanium tail, residual sand |
| Example 6 | Excellent | Excellent | Excessive glass etching |
| Example 7 | | | Occurrence of precipitation |
| Example 8 | — | — | Peeling of photosensitive film |

Cases in which the etching loss was approximately 0.5 μm±0.2 μm or less and the taper angle was approximately 30° or more, were labeled “excellent,” and cases where the etching loss was 0.5 μm±0.3 μm or less and the taper angle was 20° or more, were deemed “good.”

As shown in Table 3 and Table 4, Examples 1 to 6 were found to have excellent etching loss and taper angle. However, the etchant of Example 5 yielded undesirable titanium tails and residual sand, and the etchant of Example 6 produced excessive etching of the substrate (glass). In an actual production environment, this may correspond to excessive etching of the lower layer of the wiring, or the substrate, necessitating caution when using the etchant of Example 6.

In addition, Examples 7 and 8 did not show the etching loss and the taper angle in Table 4, but when they were etched, since the precipitation occurs or the photosensitive film was peeled, it was determined that it was not preferable to use them as the etchant. In addition, the etchant of Example 7 produced precipitation, and the etchant of Example 8 resulted in peeling of the photosensitive film. Thus, the etchants of both Examples 7 and 8 are likely not preferable for use.

In summary, the etchants of Examples 1 through 4 are preferred, as their use appears to produce better results as compared to the etchants of Examples 5 through 8.

With reference to Examples 5 to 8, 30 wt % of peroxides such as ammonium persulfates means a very large amount, 10 wt % of oxidant means a very large amount, 1.2 wt % of fluoride-based compound means a very large amount, and 0.05 wt % means a very small amount. When peroxides are contained as equal as or more than 30 wt % in an etchant, referring to Example 7, the precipitation may occur. When oxidant is contained as equal as or more than 10 wt % in an etchant, referring to Example 8, the photosensitive film may be peeled. When fluoride-based compound is contained as equal as or more than 1.2 wt %, referring to Example 6, the substrate may be excessively etched. In addition, when fluoride-based compound is contained as equal as or less than 0.05 wt %, referring to Example 5, undesirable titanium tails and residual sand are made.

Therefore, according to the experiment of the present invention, it is preferable that the etchant includes approximately 5 to 25 wt % of peroxides, approximately 0.5 to 5 wt % of oxidant, and approximately 0.1 to 1 wt % of fluoride-based compound.

The glycols act as a boiling point controlling agent for the etchant, preventing too much of the etchant from evaporating. Thus, when the amount of glycols is less than 1 wt %, too much of the etchant evaporates, and when the amount of glycols is more than 10 wt %, too much etchant remains after etching.

Therefore, in each Example, the amount of glycols is listed as 5 wt %, but this is simply reflective of a preference for the amount to be in a range of about 1 to 10 wt %.

Meanwhile, the chelating agent may be included in an amount of about 0.1 to 5 wt % and the additive may be included in an amount of about 0.1 to 5 wt %.

In addition to these, the etchants include deionized water in amounts sufficient to make the total wt % s 100.

Exemplary peroxides that can be used in the etchant include ammonium persulfate, sodium persulfate, potassium persulfate or a mixture thereof. Peroxides function to form copper oxide CuO2 by oxidizing copper. When the amount of peroxides present in the etchant is less than 5 wt %, uniform etching may not be achieved. Conversely, peroxide amounts greater than 25 wt % may result in precipitation of the peroxide.

Exemplary oxidants that can be used in the etchant include potassium hydrogen sulfate, sodium nitrate, ammonium sulfate, sodium sulfate, sodium hydrogen sulfate or a mixture thereof. The oxidant functions to substitute copper oxide that is generated by peroxide with copper nitrate (Cu NO32) and copper sulfate (CuSO4). The compound that is generated by the above procedure is water-soluble and may be dissolved in the etchant.

When the amount of oxidant is less than 0.5 wt %, the multilayer may not be smoothly etched, and when the amount is more than 5 wt %, the activity of fluorine ion that is included in the fluoride-based compound is increased, resulting in damage to the glass substrate.

Examples of the fluoride-based compound that is used in the etchant include acidic ammonium fluoride, fluorosilicic acid, potassium hydrogen fluoride or a mixture thereof. The fluoride-based compound can etch a titanium film, titanium alloy film, molybdenum film or a molybdenum alloy film.

When the amount of fluoride-based compound is less than 0.1 wt %, the titanium film, titanium alloy film, molybdenum film and molybdenum alloy film may not be smoothly etched, and when the amount is more than 1 wt %, the glass substrate or silicon film may be excessively etched.

Examples of the glycols that can be used in the etchant include ethyleneglycol, polyethyleneglycol, glycolic acid or a mixture thereof. As above, the glycols act as a boiling point controlling agent controlling the rate of evaporation of various components of the etchants, and are preferably present in amounts from about 1 wt % to about 10 wt %.

The chelating agent that is used in the etchant can be an organic chelating agent that includes an amino group and a carboxyl group, examples of which include EDTA, iminodiacetic acid, nitrilotriacetic acid, diethylene trinitrilo pentaacetic acid (DTPA) or a mixture thereof. When the etched number of metal wiring is increased, since the ion of copper or metal is increased in the etchant solution, a phenomenon that an etching ability is deteriorated is prevented.

If the chelating agent is included in an amount that is less than 0.1 wt %, when the etched number is increased, an etching ability may be deteriorated, and if it is included in an amount that is more than 5 wt %, it approaches a critical point, such that the solubility becomes poor, and thus, it may be precipitated.

Examples of the additive that can be used in the etchant include azole-based compounds (for example, 5-aminotetrazole, 1,2,3-benzotrazole, methylbenzotriazole, and/or imidazole). This additive acts to suppress etching of the copper film.

Examples of the additive are not limited, and if the additive is included in amounts less than 0.1 wt %, the copper film may be excessively etched, while if the amount of additive is more than 5 wt %, the copper film may not be sufficiently etched, resulting in, for example, a non-uniform taper angle.

The remaining wt % may be the amount of deionized water, which largely acts to dilute the other compounds in the etchant.

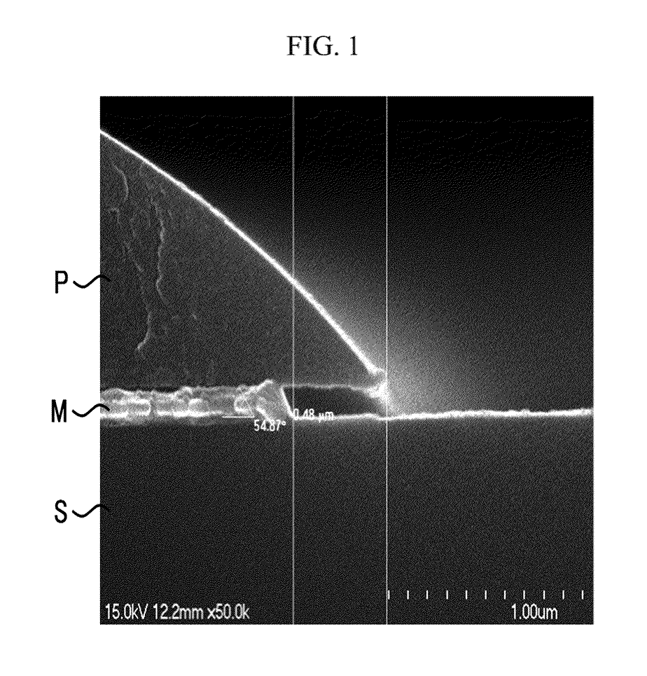

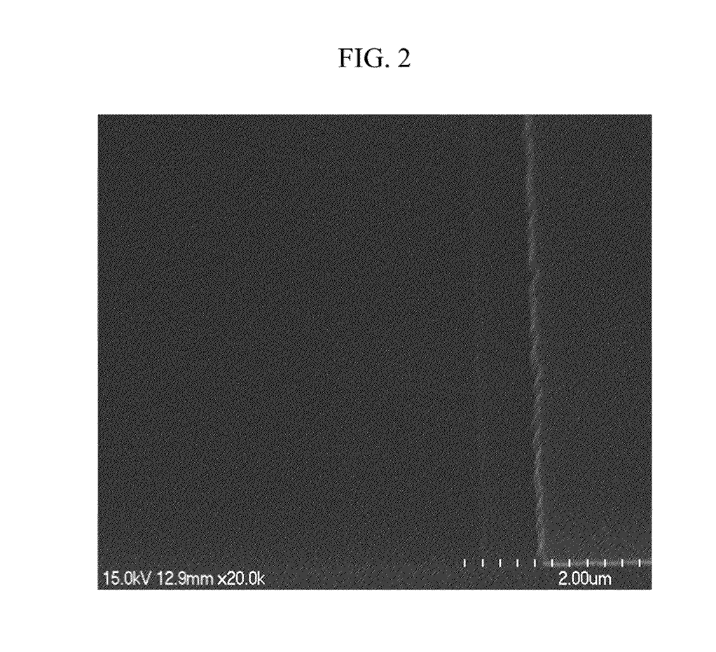

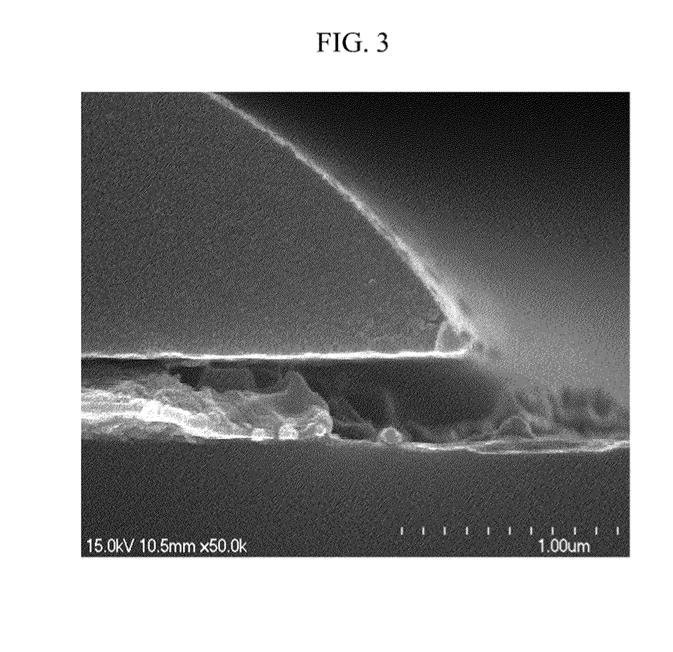

FIG. 1 and FIG. 2 illustrate etching by using the etchant of Example 1, and FIG. 3 to FIG. 5 illustrate etching by using the etchant of Example 5.

FIG. 1 is a picture that is obtained by observing the profile of the above-described titanium film/copper film using an electronic microscope, after etching is performed with the etching solution of Example 1.

In FIG. 1, the lowermost part S is a substrate, and the curvedly etched part P of the uppermost part is a photoresist layer.

The part inbetween S and P is represented by M and is an etched wiring. As above, the wiring M is a multilayer wiring that includes a lower titanium film and an upper layer copper film. The wiring M may not appear visually to have two layers, likely because the thickness of the copper film is 1200 Å, while the thickness of the titanium film is only 100 Å.

As shown in FIG. 1, since the etching loss (from the end of the photoresist layer to the end of the copper film) is 0.48 μm, and the taper angle is 54.87°, it can be confirmed that the etchant of Example 1 displays excellent etching characteristics.

FIG. 2 is a picture that is obtained by observing a glass film that is subjected to photoresist (PR) stripping of a titanium film/copper film using an electronic microscope after etching is performed by using the etchant according to Example 1. As shown in FIG. 2, after the etching, since no tail or residual sand of titanium appears to be present, it can be confirmed that the etching is excellent.

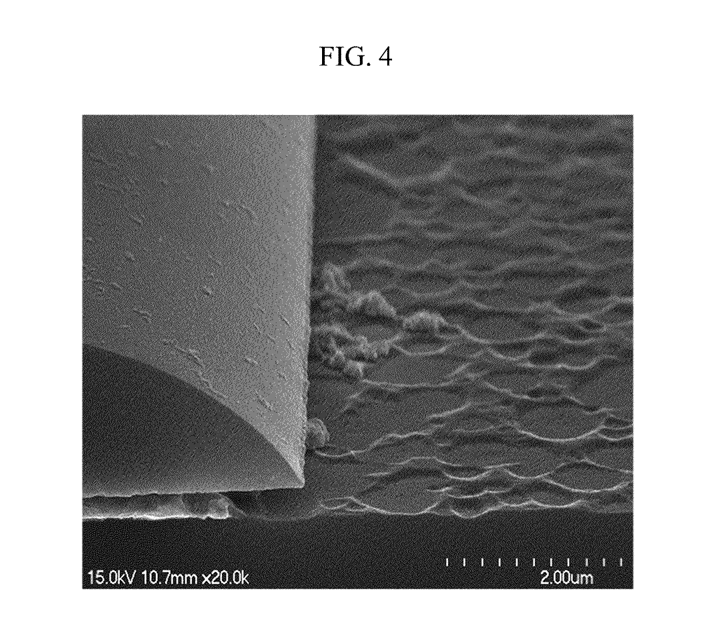

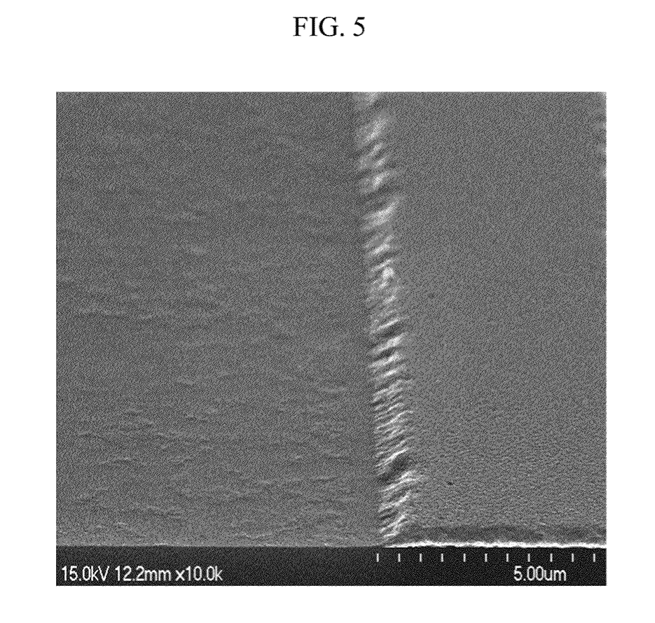

FIG. 3 and FIG. 4 are pictures that are obtained by observing a profile of the titanium film/copper film using an electron microscope after etching is performed by using an etchant according to Example 5. FIG. 5 is a picture that is obtained by observing a glass film that is subjected to photoresist (PR) stripping of a titanium film/copper film using an electronic microscope after etching is performed by using an etchant according to Example 5.

As shown in FIG. 3 to FIG. 5, since a titanium tail and the residual sand remain after the etching, the etchant of Example 5 likely does not produce desirable results.

In the above, the titanium film may be changed to a molybdenum film or a molybdenum alloy film, since the fluoride-based compound used in the etchant etches a molybdenum film or a molybdenum alloy film.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. An etchant for metal wiring, comprising: approximately 5 to approximately 25 wt % of a peroxide, approximately 0.5 to approximately 5 wt % of an oxidant, approximately 0.1 to approximately 1 wt % of a fluoride-based compound, and approximately 1 to approximately 10 wt % of a glycol.

2. The etchant of claim 1, wherein:
the peroxide comprises ammonium persulfate, sodium persulfate, potassium persulfate, or a mixture thereof.

3. The etchant of claim 2, wherein:
the oxidant comprises potassium hydrogen sulfate, sodium nitrate, ammonium sulfate, sodium sulfate, sodium hydrogen sulfate, or a mixture thereof.

4. The etchant of claim 3, wherein:
the fluoride-based compound comprises acidic ammonium fluoride, fluorosilicic acid, potassium hydrogen fluoride, or a mixture thereof.

5. The etchant of claim 1, further comprising:
a chelating agent.

6. The etchant of claim 5, wherein:
the chelating agent comprises an organic chelating agent, the organic chelating agent further comprising an amino group and a carboxyl group.

7. The etchant of claim 6, wherein:
the chelating agent comprises EDTA, iminodiacetic acid, nitrilotriacetic acid, diethylene trinitrilo pentaacetic acid (DTPA), or a mixture thereof.

8. The etchant of claim 5, wherein the etchant comprises approximately 0.1 to approximately 5 wt % of the chelating agent.

9. The etchant of claim 1, wherein:
the glycol comprises ethyleneglycol, polyethyleneglycol, glycolic acid, or a mixture thereof.

10. The etchant of claim 1, wherein the etchant further comprises approximately 0.1 to approximately 5 wt % of the additive.

11. The etchant of claim 10, wherein:
the additive further comprises an azole-based compound.

12. The etchant of claim 1, wherein:
the etchant is applied to etch a multilayer wiring that comprises a copper film.

13. The etchant of claim 12, wherein:
the multilayer wiring comprises a first layer that comprises copper and a second layer that comprises titanium or molybdenum.

14. A method for manufacturing a thin film transistor array panel, the method comprising the steps of:
forming a gate line that comprises a gate electrode,
forming a data line that crosses the gate line, and
forming a semiconductor that overlaps the gate electrode,
wherein at least one of the forming a gate line and forming a data line comprises:
layering a multilayer wiring that comprises copper, and
etching the multilayer wiring with an etchant that comprises approximately 5 to approximately 25 wt % of a peroxide, approximately 0.5 to approximately 5 wt % of an oxidant, approximately 0.1 to approximately 1 wt % of a fluoride-based compound, and approximately 1 to approximately 10 wt % of a glycol.

15. The method for manufacturing a thin film transistor array panel of claim 14, wherein:
the peroxide comprises ammonium persulfate, sodium persulfate, potassium persulfate, or a mixture thereof.

16. The method for manufacturing a thin film transistor array panel of claim 15, wherein:
the oxidant comprises potassium hydrogen sulfate, sodium nitrate, ammonium sulfate, sodium sulfate, sodium hydrogen sulfate, or a mixture thereof.

17. The method for manufacturing a thin film transistor array panel of claim 16, wherein:
the fluoride-based compound comprises acidic ammonium fluoride, fluorosilicic acid, potassium hydrogen fluoride, or a mixture thereof.

18. The method for manufacturing a thin film transistor array panel of claim 14, wherein:
the etchant further comprises a chelating agent.

19. The method for manufacturing a thin film transistor array panel of claim 14, wherein:
the etchant further comprises an azole-based compound as an additive.
